(19) United States
(12) Patent Application Publication
(10) Pub. No.: US 2015/0127284 A1
(43) Pub. Date: May 7, 2015

(54) Sensor Data Time Alignment

(71) Applicant: Microsoft Corporation, Redmond, WA (US)

(72) Inventors: Natarajan Kurian Seshan, Bothell, WA (US); Tom Savell, Santa Cruz, CA (US)

(73) Assignee: Microsoft Corporation, Redmond, WA (US)

(21) Appl. No.: 14/275,556

(22) Filed: May 12, 2014

Related U.S. Application Data
(60) Provisional application No. 61/899,259, filed on Nov. 3, 2013.

(51) Int. Cl. H03K 5/135; G01D 3/02

(52) U.S. Cl. CPC H03K 5/135; G01D 3/022
USPC 702/89

(57) ABSTRACT

Techniques for sensor data time alignment are described. According to one or more embodiments, sensor data from different sensor systems is time-aligned to a reference time base. For instance, reference time values may be propagated to sensor systems to enable the sensor systems to mark sensor data based on the reference time values. Sensor data from a sensor system may be time-aligned by applying an alignment policy to the sensor data. An alignment policy, for example, accounts for a difference between a time base of a sensor system and a reference time base. Thus, sensor data from different sensor systems may be aligned to common time values in a variety of different ways.

### RELATED APPLICATION

This application claims priority under 35 U.S.C. §119(e) to U.S. Provisional Patent Application No. 61/899,259, entitled “Sensor Data Time Alignment” and filed on Nov. 3, 2013, the disclosure of which is incorporated in its entirety by reference herein.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Techniques for sensor data time alignment are described. According to one or more embodiments, sensor data from different sensor systems is time-aligned to a reference time base. For instance, reference time values may be propagated to sensor systems to enable the sensor systems to mark sensor data based on the reference time values. Sensor data from a sensor system may be time-aligned by applying an alignment policy to the sensor data. An alignment policy, for example, accounts for a difference between a time base of a sensor system and a reference time base. Thus, sensor data from different sensor systems may be aligned to common time values in a variety of different ways.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items.

FIG. 1 is an illustration of an environment in an example implementation that is operable to employ techniques discussed herein.

FIG. 2 illustrates an example implementation scenario for time aligning sensor data in accordance with one or more implementations.

FIG. 3 illustrates an example implementation scenario for time-aligning sensor data in accordance with one or more implementations.

FIG. 4 illustrates an example implementation scenario for coalescing sensor data from multiple devices in accordance with one or more implementations.

FIG. 5 is a flow diagram that describes steps in a method for aligning sensor data with a reference time base in accordance with one or more embodiments.

FIG. 6 is a flow diagram that describes steps in a method for timestamping sensor data based on a reference time base in accordance with one or more embodiments.

FIG. 7 is a flow diagram that describes steps in a method for time-aligning sensor data based on a reference time base in accordance with one or more embodiments.

FIG. 8 is a flow diagram that describes steps in a method for tracking alignment policies for sensor systems in accordance with one or more embodiments.

FIG. 9 is a flow diagram that describes steps in a method for coalescing sensor data from different sensor systems in accordance with one or more implementations.

FIG. 10 illustrates an example system and computing device as described with reference to FIG. 1, which are configured to implement embodiments of techniques described herein.

### DETAILED DESCRIPTION

Overview

Many computing devices have multiple sensors that can be employed to sense different types of environmental phenomena. Examples of such sensors include location sensors, orientation sensors, audio sensors, video sensors (e.g., a camera), touch sensors, biometric sensors, climate (e.g., temperature, pressure, humidity, and so forth), network activity, time, and so on. Sensors may also include functionality for detecting system state conditions, such as logic states of system processes, device states, network-related states, and so forth.

In at least some embodiments, “sensor systems” are defined based on one or more sensors. For instance, an orientation sensor system may include a collection of sensors such as a gyroscope, and accelerometer, and so forth. Data from the different sensors of a sensor system can be processed and/or combined to determine various environmental conditions. Further, input from multiple sensor systems can be considered in determining various environmental conditions.

Techniques for sensor data time alignment are described. Embodiments discussed herein enable buffering and annotating of sensor data streams from different sensor systems to enable precise calculation of sensor input relative to other state conditions of an overall environment. As used herein, the term “environment” may refer to physical phenomena, such as geographical location, light, sound, physical orientation, and so forth. Environment may additionally or alternatively refer to system state conditions, such as for a computing device and/or multiple computing devices, for a network, for a cloud-based architecture, and so forth.

In at least some implementations, sensor data from a sensor system can be time-aligned in a variety of ways. For instance, a reference time clock can be utilized that provides an indication of system time to different sensor systems. The sensor systems can each mark their respective sensor data with time data received from the reference time clock. Thus, sensor data streams from the different sensor systems can be aligned based on common time values from the reference time clock. Time aligning data from different sensor systems enables fusion of data from the different systems into a coherent data stream that can be consumed in various ways.

Techniques discussed herein not only apply to raw data from a sensor system, but also to data that is derived from processing of raw sensor data. For example, wave form data from an audio sensor can be time aligned, as well as words recognized via speech recognition of words that occur in the wave form data. Thus, “sensor data” may refer to both raw sensor data and processed sensor data.

According to one or more implementations, sensor data from a sensor system is associated with an alignment policy that enables the sensor data to be aligned with a reference time value. Generally, an alignment policy describes a relationship between sensor data provided by a sensor system and a reference time value. An example alignment policy, for instance, describes a sampling frequency of a sensor system relative to a reference time clock, e.g., relative to a master time clock for a system. Other examples of alignment policies include values such as skews between a local clock of a sensor system and a reference time clock of a device, periodicity of sensor data collection for a sensor system, and so forth.

Accordingly, an alignment policy may be based on a single parameter value that can be applied to sensor data, a combination of parameters, an algorithm that may include multiple input values, and so forth. When a sensor system emits sensor data, the sensor data can be processed based on an alignment policy for the sensor system to time-align the sensor data.

In some example implementations, a sensor system can include a time clock that is reconciled to a reference time clock for a system. For instance, for an individual sensor system, an alignment policy can be determined that describes a difference between an internal time clock of the sensor system and a reference time clock for a system. The alignment policy can be implemented in a variety of ways, such as a time difference between an internal time clock of a sensor system and a master system clock. The alignment policy may be implemented in a variety of other ways, such as a difference in operating frequency between an internal time clock of a sensor system and a master system clock, a multiple value that can be applied to a time value from an internal time clock of a sensor system to reconcile the time value to a master clock, and so forth. In at least some embodiments, an alignment policy may be periodically refreshed (e.g., based on a specified time interval), and/or is refreshed based on various events, such as changes in operating conditions of a system.

Thus, techniques discussed herein enable sensor data from sensor systems that may operate according to different time bases to be time-aligned. This enables rich sets of time-aligned sensor data to be leveraged by various functionalities to perform different tasks.

In the following discussion, an example environment is first described that is operable to employ techniques described herein. Next, a section entitled “Example Scenarios” discusses some example scenarios for sensor data time alignment techniques in accordance with one or more implementations. Following this, a section entitled “Example Procedures” describes some example procedures in accordance with one or more embodiments. Finally, a section entitled “Example System and Device” describes an example system and device that are operable to employ techniques discussed herein in accordance with one or more embodiments.

Example Operating Environment

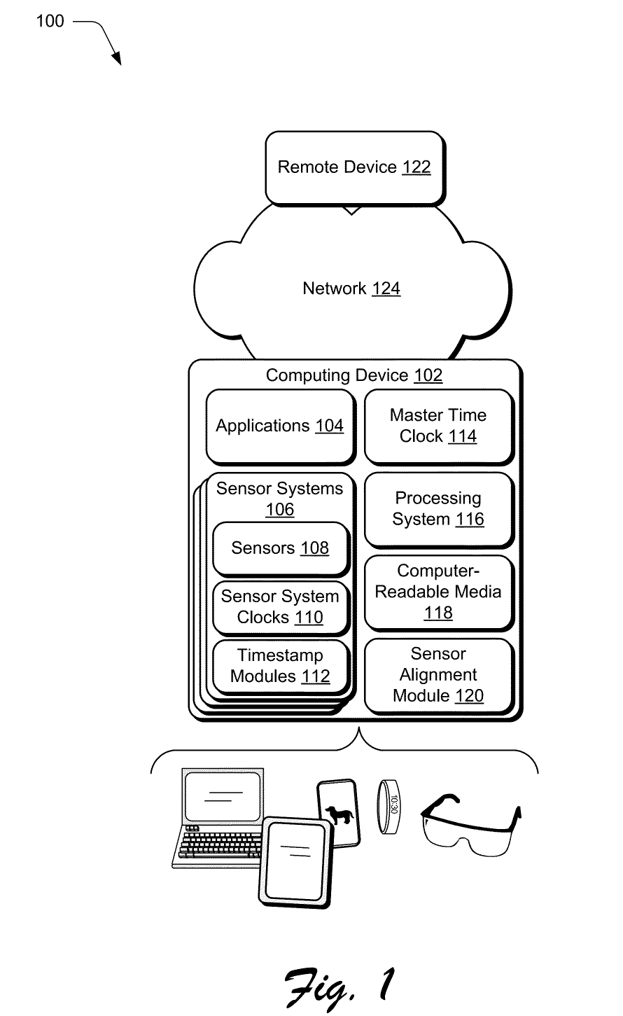

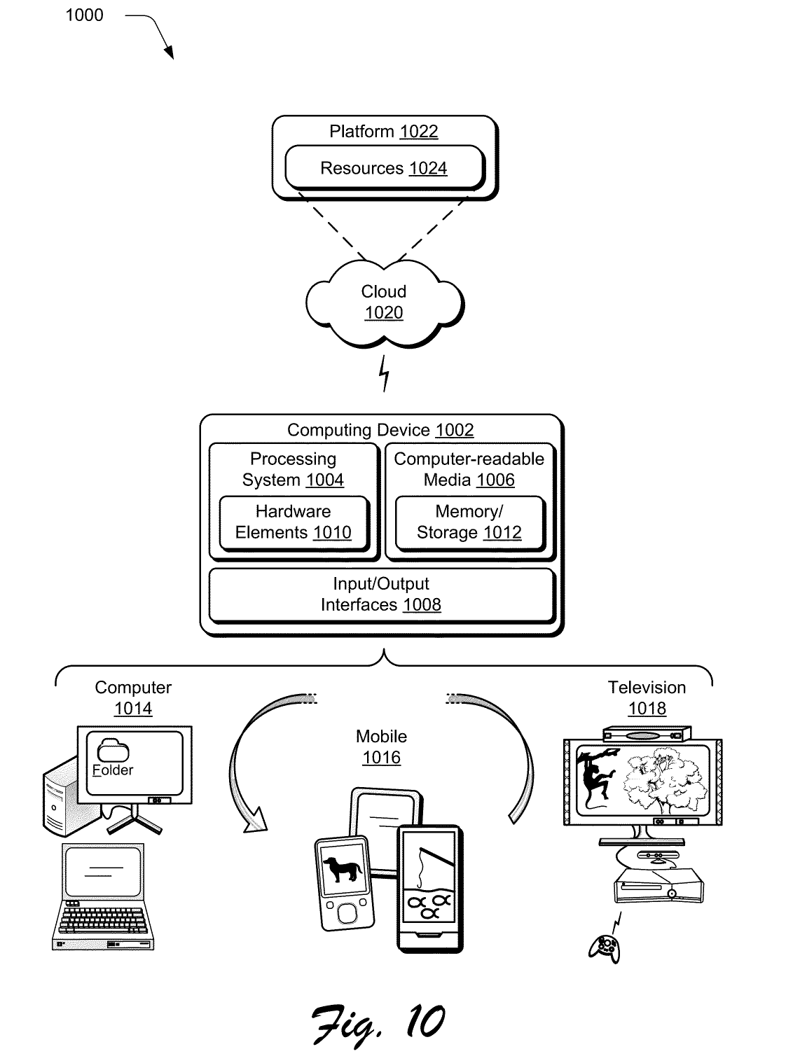

FIG. 1 is an illustration of an environment 100 in an example implementation that is operable to employ techniques for sensor data time alignment described herein. The illustrated environment 100 includes a computing device 102, which may be configured in a variety of ways. For example, the computing device 102 may be configured for mobile use, such as a mobile phone, a tablet computer, a laptop computer, a wearable device, and so on. Alternatively or additionally, the computing device 102 may be configured for other usage scenarios. Thus, the computing device 102 may range from full resource devices with substantial memory and processor resources to a low-resource device with limited memory and/or processing resources. The computing device 102 may also include software that causes the computing device 102 to perform one or more operations. Example implementation details concerning the computing device 102 are discussed below with reference to FIG. 10.

The computing device 102 includes various applications 104 that provide different functionality to the computing device 102. A variety of applications 104 typically associated with computing devices are contemplated including, but not limited to, an operating system, a productivity suite that integrates multiple productivity modules (e.g., for enterprise-related tasks), a web browser, games, a multi-media player, a word processor, a spreadsheet program, a content manager, and so forth.

Multiple sensor systems 106 are installed on and/or operably associated with the computing device 102. Generally, the sensor systems 106 are configured to sense various phenomena relative to the computing device 102. The individual sensor systems 106 may include one or multiple types and instances of sensors 108. Examples of the sensors 108 include an accelerometer, a camera, a microphone, biometric sensors, touch input sensors, position sensors, and so forth. One or more of the sensors 108 may be configured to detect other types of phenomena, such as time (e.g., internal and/or external time), various types of device state, logic state, process state (e.g., application state), and so forth. The sensors 108 may include a variety of other types and instances of sensors not expressly mentioned herein.

The sensor systems 106 may be individually associated with different types of phenomena. For instance, a particular sensor system 106 may be configured to sense image input, such as via cameras and/or other types of light sensors. Another sensor system 106 may be configured to detect audio input, such as via microphone. Still another sensor system 106 may be configured to detect various internal state attributes of the computing device 102, such as process state, application state, hardware state, and so forth. Thus, the sensor systems 106 may combine to provide an array of sensing capabilities for the computing device 102.

In accordance with techniques described herein, sensor data obtained by and/or from the sensor systems 106 may be processed and/or combined in a variety of ways according to embodiments discussed herein. For instance, sensor data streams from the different sensors 108 can be timestamped in various ways to enable the data streams to be correlated to provide a time accurate picture of sensor output from the different sensor systems.

The sensor systems 106 include sensor system clocks 110 and timestamp modules 112. Generally, the sensor system clocks 110 are representative of internal time clocks for the respective sensor systems 106. In at least some implementations, the sensor system clocks 110 represent an internal processing and/or sampling mechanism of the sensor systems 106 that operate according to a particular processing and/or sampling rate. A particular sensor system clock 110, for instance, may represent a processing unit of a respective sensor system 106.

The timestamp modules 112 are representative of functionality to enable sensor data from the sensors 108 to be timestamped according to one or more embodiments. In at least some embodiments, the sensor system clocks 110 and/or the timestamp modules 112 are optional, and one or more of the sensor systems 106 may not utilize a sensor system clock 110 and/or a timestamp module 112.

The computing device 102 further includes a master time clock 114, which is representative of a master time clock for the computing device 102. The master time clock 114, for instance, represents an internal clock that is utilized to synchronize various functionality of the computing device 102. In at least some implementations, the master time clock 114 may represent a processing unit of the computing device 102, e.g., a central processing unit (CPU). According to embodiments discussed herein, time information from the master time clock 114 can be utilized by the sensor systems 106 to time stamp their respective sensor data.

While the computing device 102 is discussed with reference to utilizing the master time clock 114 for purposes of alignment, other implementations may alternatively or additionally use other types of alignment mechanisms. For instance, embodiments may not utilize a master clock internal to a particular device. For example, a virtual clock different than the master time clock 114 may be implemented that is utilized to time align sensor data, and/or other ways of aligning sensor data that do not necessarily use the master time clock 114.

The computing device 102 further includes a processing system 116 and computer-readable media 118 that are representative of various different types and combinations of processing components, media, memory, and storage components and/or devices that may be associated with the computing device 102 and employed to provide a wide range of device functionality. In at least some embodiments, the processing system 116 and computer-readable media 118 represent processing power and memory/storage that may be employed for general purpose computing operations. The processing system 116, for instance, represents a CPU of the computing device 102.

A sensor alignment module 120 is included, which is representative of functionality to implement aspects of sensor time alignment techniques described herein. For example, the sensor alignment module 120 generally represents functionality to align sensor data with a reference time representation (e.g., from the master time clock 114 and/or other time representation) according to various embodiments discussed herein. The sensor alignment module 120 may also receive sensor data from the sensor systems 106 that has already been timestamped (e.g., by the sensor systems 106 themselves) and can align different sets of sensor data from different of the sensor systems 106 based on common timestamps. In at least some implementations, the sensor alignment module 120 may propagate a reference time value (e.g., from the master time clock 114) to the sensor systems 106 to enable the sensor systems to utilize the reference time value to timestamp their respective sensor data.

The environment 100 further includes a remote device 122 which is communicably connected to the computing device 102 via a network 124. According to one or more implementations the remote device 122 is considered “remote” in the sense that it separate from the computing device 102 and represents an independently-functioning device. For instance, the remote device 122 may be in the same general location as the computing device 102 (e.g., in the same room), or may be some distance from the computing device. The remote device 122 may be implemented in a variety of ways, examples of which are discussed above with regard to the computing device 102, and below with reference to the system 1000.

In at least some implementations, the remote device 122 includes at least some of the functionality discussed above with reference to the computing device 102. For instance, the remote device 122 includes its own particular sensors and/or sensor systems, and may include various time alignment functionalities discussed above. As further detailed below, sensor data from the computing device 102 and the remote device 122 may be time aligned to a reference time base to enable an aggregated set of sensor data to be generated that includes aligned sensor data from both the computing device 102 and the remote device 122.

The network 124 is generally representative of functionality to provide wired and/or wireless connectivity, such as between the computing device 102, the remote device 122, and/or other entities and networks. The network 124 may provide connectivity via a variety of different technologies, such as local access network (LAN), wide area network (WAN), the Internet, various of the 802.11 standards, WiFi™, Bluetooth, infrared (IR) data transmission, near field communication (NFC), and so forth.

Having discussed an example environment in which embodiments may operate, consider now some example operating scenarios in accordance with one or more implementations.

Example Scenarios

The following discussion describes some example scenarios for sensor time alignment techniques that may be implemented utilizing the previously described systems and devices and/or other systems and devices not expressly discussed herein. Aspects of the scenarios may be implemented in hardware, firmware, software, or combinations thereof.

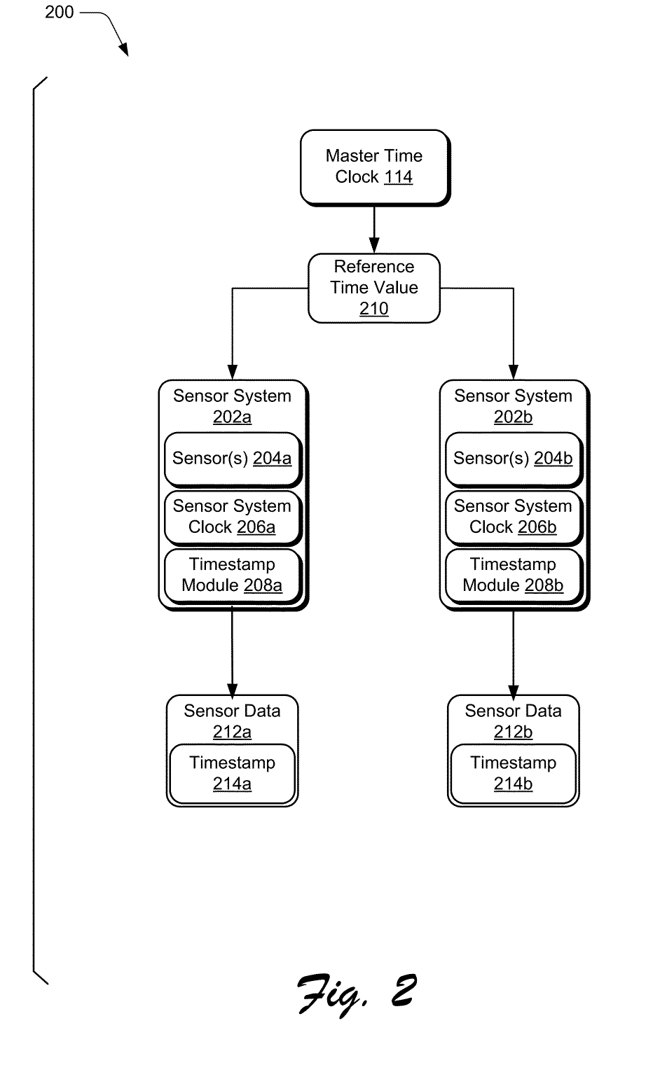

FIG. 2 illustrates an example operating scenario 200 for time aligning sensor data in accordance with one or more implementations. The scenario 200 includes sensor systems 202a, 202b, which represent implementations of the sensor systems 106 introduced above. The sensor systems 202a, 202b include respective implementations of sensors 204a, 204b, sensor system clocks 206a, 206b, and timestamp modules 208a, 208b. According to various implementations, the sensors 204a, 204b represent different respective types, instances, and/or combinations of sensors.

In the scenario 200, a reference time value 210 from the master time clock 114 is propagated to the sensor systems 202a, 202b. The reference time value 210, for example, represents a system time value at a discrete point in time that is employed to coordinate various system processes, such as for the computing device 102 discussed above. In at least some embodiments, the reference time value 210 is based on a processor clock rate for a processing unit (e.g., CPU) of a computing device.

The reference time value 210 can be propagated to the sensor systems 202a, 202b in a variety of different ways. For instance, the master time clock 114 may periodically and/or continuously communicate the reference time value 210 to the sensor systems 202a, 202b. Alternatively or additionally, the sensor systems 202a, 202b may query the master time clock 114 for the reference time value 210. As another example, various events may cause the reference time value 210 to be communicated to the sensor systems 202a, 202b. Examples of such events include a power-on event, a launch of an application that utilizes a particular sensor system, a request for sensor data from a sensor system (e.g., from an application or other process), and so forth.

Further to the scenario 200, the sensor systems 202a, 202b may utilize the reference time value 210 in various ways. For instance, the sensor systems 202a, 202b may utilize the reference time value 210 as it is received to mark sensor data. Alternatively or additionally, the sensor system clocks 206a, 206b may be synchronized with the reference time value 210 to enable the sensor systems 202a, 202b to be synchronized with the master time clock 114.

Continuing with the scenario 200, the sensor systems 202a, 202b emit sensor data that is timestamped based on the reference time value 210. For instance, the sensor system 202a emits sensor data 212a that includes a timestamp 214a. Further, the sensor system 202b emits sensor data 212b that includes a timestamp 214b. The timestamps 214a, 214b can be associated with the sensor data 212a, 212b, respectively, in various ways. For instance, a timestamp may be used to annotate a packet header of a respective instance of sensor data. Alternatively or additionally, a timestamp may be implemented as a separate, parallel data structure that is linked to a respective instance of sensor data. As yet another example, a timestamp may be inserted into the sensor data itself. Thus, timestamps may be correlated to respective instances of sensor data utilizing a variety of different techniques.

Generally, the timestamps 214a, 214b represent time values that indicate “when” phenomena represented by the respective sensor data 212a, 212b was detected relative to the reference time value 210. For instance, as the reference time value 210 is received by the sensor systems 202a, 202b, the sensor systems can immediately mark the sensor data 212a, 212b with the respective timestamps 214a, 214b. Thus, in at least some implementations, the timestamps 214a, 214b represent the same time value as the reference time value 210.

As referenced above, the reference time value 210 may be utilized to set the sensor system clocks 206a, 206b. Accordingly, the timestamps 214a, 214b may be generated based on time values from the sensor system clocks 206a, 206b.

In another example implementation, the reference time value 210 can be utilized as a baseline time value and the sensor systems 202a, 202b (e.g., via their respective timestamp modules) can generate the timestamps 214a, 214b to include the reference time value 210 plus a delta value that represents elapsed time since the reference time value 210 was received. The reference time value 210, for instance, can be used as a starting time for a counter that calculates elapsed time from the reference time value 210.

The scenario 200 can be repeated (e.g., periodically) over time to generate sets of time-aligned sensor data from the sensor systems 202a, 202b. For instance, updated reference time values may be continually and/or periodically propagated to the sensor systems 202a, 202b to enable the sensor systems to remain synchronized with the master time clock 114. As further detailed below, the sensor data 212a, 212b can be communicated to different entities and/or processes to be leveraged for various purposes.

While the scenario 200 is discussed with reference to the sensor systems 202a, 202b implementing common techniques, this is not to be construed as limiting. For instance, in at least some implementations, the sensor systems 202a, 202b may individually leverage different techniques discussed herein to generate time-aligned sensor data. Further, implementations are not limited in the number of sensor systems that may be employed, and techniques discussed herein may be employed to enable multiple sensor systems (e.g., 3 or more) to generate time-aligned sensor data.

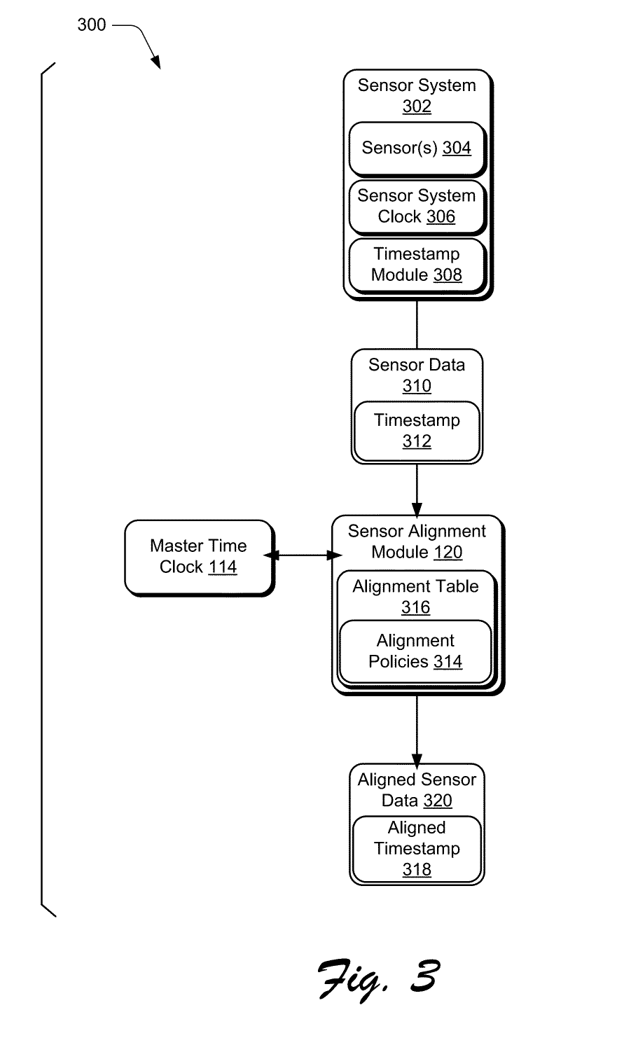

FIG. 3 illustrates an example operating scenario 300 for time-aligning sensor data in accordance with one or more implementations. The scenario 300 includes a sensor system 302, which represents an implementation of a sensor system 106 introduced above. The sensor system 302 includes one or more sensors 304, a sensor system clock 306, and a timestamp module 308.

In the scenario 300, the sensor system 302 emits sensor data 310 which includes a timestamp 312. The timestamp 312 includes a time value that specifies a time at which the sensor data 310 was detected by the sensor 304. The time value, for instance, is based on a time specified by the sensor system clock 306.

Further to the scenario 300, the sensor alignment module 120 receives the sensor data 310 and determines an alignment policy 314 for the sensor system 302 from an alignment table 316. Generally, the alignment policy 314 represents a time correction and/or time skew value that can be applied to the timestamp 312 to align the timestamp 312 with a reference time value, e.g., as specified by the master time clock 114. For example, the alignment policy 314 describes a relative relationship between time values generated by the sensor system clock 306 and the master time clock 114. In at least some implementations, the alignment table 316 is implemented as part of a data storage location in which alignment policies and/or other alignment-related information may be stored.

The alignment policy 314, for instance, enables a time value specified by the sensor system clock 306 to be aligned with a time value specified by the master time clock 114 at a discrete instance. The alignment policy 314 can be specified in various ways, such as a time interval value (e.g., in microseconds, milliseconds, and so forth), a ratio, an equation, and so forth.

In an example implementation, the alignment policy 314 can be based on a known clock rate (e.g., processor clock rate) for the sensor system 302. The clock rate, for example, refers to a sampling frequency and/or sampling rate for the sensor system 302. For instance, the sensor system 302 may have a clock rate of 60 Hertz (Hz), which may be reflected in the alignment policy 314. In at least some implementations, the clock rate of the sensor system clock 306 may be tracked relative to a reference clock rate of the master time clock 114 to enable sensor data emitted by the sensor system 302 to be synchronized with the master time clock 114.

According to one or more implementations, the alignment table 316 maintains alignment policies for different sensor systems. For instance, the alignment table correlates identifiers for different sensor systems with alignment policies for the respective sensor systems. In at least some implementations, alignment policies may be specific to their respective sensor systems, e.g., a particular sensor system may have a different alignment policy than another sensor system.

For instance, the sensor data 310 may include an identifier for the sensor system 302. When the sensor data 310 is received, the sensor alignment module 120 can use the identifier to look up the alignment policy 314 for the sensor system 302 in the alignment table 316. Thus, different sensor systems may be associated with different system identifiers that enable alignment policies for the different sensor systems to be located. Example ways for generating alignment policies are discussed below.

Continuing with the scenario 300, the sensor alignment module 120 applies the alignment policy 314 to the timestamp 312 to generate an aligned timestamp 318. The alignment policy 314 can be applied to the timestamp 312 in various ways, such as adding or subtracting the alignment policy 314 to/from the timestamp 312, multiplying the timestamp 312 by the alignment policy 314, utilizing the timestamp 312 and the alignment policy 314 as values for variables in an equation, and so forth.

According to various implementations, the aligned timestamp 318 represents a time value that is synchronized with a reference time value indicated by the master time clock 114 for a discrete instance. For example, consider that the sensor data 310 is captured by the sensor 304 at a reference time value T_{R} as specified by the master time clock 114. When the sensor data 310 is initially captured at T_{R}, the timestamp module 308 marks the sensor data 310 with a time value T_{S} (e.g., as read from the sensor time clock 306) as part of the timestamp 312. However, T_{S} is not aligned (e.g., is not equal to) T_{R}. Thus, in at least some implementations, applying the alignment policy 314 to T_{S} generates a time value T_{A} for the aligned timestamp 318, where T_{A} is equal to or approximately equal to T_{R}.

The sensor data 310 is then marked with the aligned timestamp 318 to generate aligned sensor data 320. The aligned sensor data 320, for instance, includes the same sensor data as sensor data 310, but marked with the aligned timestamp 318. The aligned timestamp 318 can be associated with the aligned sensor data 320 in various ways. For instance, the aligned timestamp 318 may be used to annotate a buffer header and/or packet header of the aligned sensor data 320. Alternatively or additionally, the aligned timestamp 318 may be implemented as a separate, parallel data structure (e.g., metadata) that is linked to the aligned sensor data 320. As yet another example, the aligned timestamp 318 may be inserted into the aligned sensor data 320 itself. Thus, timestamps may be correlated to respective instances of sensor data utilizing a variety of different techniques.

The aligned sensor data 320 can be communicated to various entities, such as applications, processes, and/or functionalities that can leverage the aligned sensor data 320 for different purposes.

The techniques discussed with reference to the scenarios 200 and 300 are not to be construed as mutually exclusive, and implementations may combine the various techniques to align sensor data. In a device and/or system, for instance, a particular sensor system may use techniques discussed with reference to FIG. 2, whereas another sensor system may utilize techniques discussed with reference to FIG. 3. Further, particular events and/or conditions may cause a particular sensor system to switch between the techniques discussed in the scenarios 200 and 300.

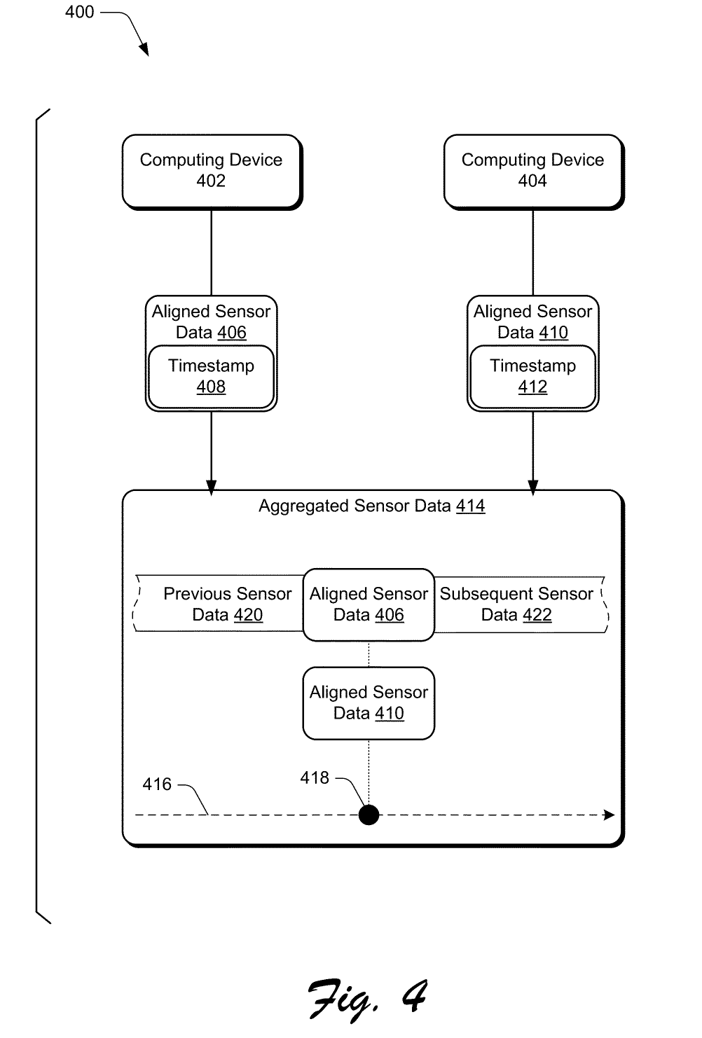

FIG. 4 illustrates an example operating scenario 400 for coalescing sensor data from multiple devices in accordance with one or more implementations. The scenario 400 includes a computing device 402 and a computing device 404. In at least some implementations, the computing devices 402, 404 represent embodiments of the computing device 102 and the remote device 122, respectively.

In the scenario 400, the computing device 402 generates sensor data that is time-aligned to generate aligned sensor data 406 that includes a timestamp 408. Further, the computing device 404 generates sensor data that is time-aligned to generate aligned sensor data 410 that includes a timestamp 412. The timestamps 408, 412 may be generated using one or more of the techniques discussed herein, such as above with reference to FIGS. 2 and 3.

According to one or more implementations, the aligned sensor data 406 and the aligned sensor data 410 may represent different respective types of sensor data. For instance, the aligned sensor data 406 may include audio data sensed by one or more audio sensors of the computing device 402, and the aligned sensor data 410 may include image and/or video data sensed by an image and/or video sensor (e.g., camera) of the computing device 404. This is not intended to be limiting, however, and in one or more implementations the aligned sensor data 406 and the aligned sensor data 410 may include one or more common types of sensor data.

Further to the scenario 400, a determination is made that the timestamps 408, 412 correspond to the same time value, e.g., share a common time value. For example, for a time value T_{R′} (such as generated by the master time clock 114), the timestamps 408, 412 are equal to or approximately equal to T_{R′}. Accordingly, the aligned sensor data 406 and the aligned sensor data 410 are coalesced as part of aggregated sensor data 414. Generally, the aggregated sensor data 414 maintains sensor data from different devices and/or systems that is aligned by correlating common time values, e.g., common timestamps. For instance, the aggregated sensor data 414 includes a sensor data timeline 416 that correlates specific time values with sensor data for matching timestamps. The aligned sensor data 406, 410, for example, are correlated to a time value 418 of the sensor data timeline 416 that matches the timestamps 408, 412.

The aggregated sensor data 414 further includes previous sensor data 420 and may optionally include subsequent sensor data 422. Generally, the previous sensor data 420 represents sensor data with timestamps that occur earlier than the time value 418, and the subsequent sensor data 422 represents sensor data with timestamps that occur later than the time value 418. The previous sensor data 420 and the subsequent sensor data 422 may be received from the computing device 402, the computing device 404, and/or other device and/or entity.

Accordingly, the aggregated sensor data 414 includes sensor data from different devices, systems, and/or entities that is aligned to common time values and/or timestamps. Sensor data from the aggregated sensor data 414 can be retrieved and/or consumed in various ways, such via queries for sensor data from a particular time value and/or time interval, a query for sensor data from a particular device and/or set of devices, and so forth.

While the aggregated sensor data 414 is discussed with reference to sensor data from the computing devices 402, 404, this is not intended to be limiting. For instance, the aggregated sensor data 414 may maintain sensor data from a single device (e.g., from multiple sensor systems) and/or from multiple devices in addition or alternatively to the computing devices 402, 404.

According to various implementations, the aggregated sensor data 414 may be generated and/or maintained by a particular device and/or entity, such as the computing device 402, the computing device 404, and/or other system or resource.

Having described some example scenarios according to techniques described herein, consider now a discussion of some example procedures in accordance with one or more implementations.

Example Procedures

The following section describes some example procedures for time-aligned sensor data in accordance with one or more embodiments. The example procedures may be employed in the environment 100 of FIG. 1, the system 1000 of FIG. 10, and/or any other suitable environment. In at least some embodiments, steps described for the various procedures are implemented automatically and independent of user interaction.

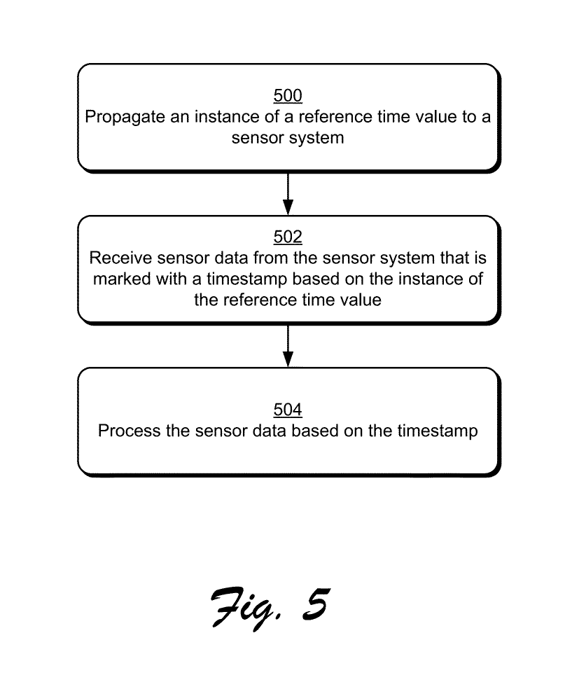

FIG. 5 is a flow diagram that describes steps in a method in accordance with one or more embodiments. The method, for instance, describes an example way of aligning sensor data with a reference time base in accordance with one or more implementations.

Step 500 propagates an instance of a reference time value to a sensor system. A time value from a master time clock, for instance, can be propagated to one or more sensor systems.

Step 502 receives sensor data from the sensor system that is marked with a timestamp based on the instance of the reference time value. The timestamp, for instance, may include the reference time value, may be marked with the reference time value plus a delta value that represents an elapsed time since the reference time value, and so forth.

Step 504 processes the sensor data based on the timestamp. The sensor data, for example, may be arranged with other sensor data based on respective timestamps, e.g., chronologically. For instance, different instances of sensor data with the same and/or similar timestamps may be grouped together to represent a collection of sensed phenomena that occurred at a particular time.

According to various implementations, this method can be performed periodically and/or continuously to provide updated reference time values to a sensor system.

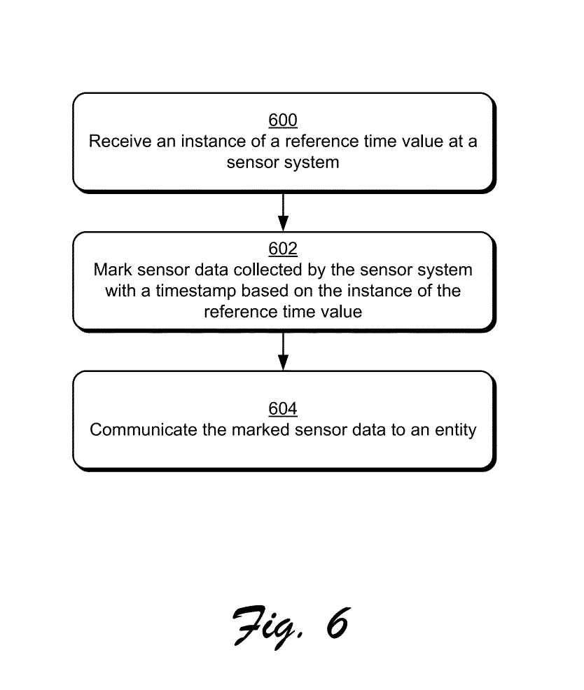

FIG. 6 is a flow diagram that describes steps in a method in accordance with one or more embodiments. The method, for instance, describes an example way of timestamping sensor data based on a reference time base in accordance with one or more implementations.

Step 600 receives an instance of a reference time value at a sensor system. The reference time value, for example, is received from a functionality that is external to the sensor system, e.g., a master time clock.

Step 602 marks sensor data collected by the sensor system with a timestamp based on the instance of the reference time value. The sensor data, for instance, is timestamped with the reference time value to indicate that the sensor data was sensed at the same time that the reference time value was received, e.g., synchronously with the reference time value being received.

As referenced above, the reference time value may be utilized by a sensor system as a baseline time value to synchronize an internal clock of the sensor system and/or to initiate and/or mark a counter starting with the reference time value. For instance, when an internal clock of a sensor system is set using a reference time value, time values from the internal clock can be used to timestamp sensor data. When the reference time value is used to start and/or mark a counter, sensor data can be marked with the reference time value plus a delta value that represents an elapsed time since the reference time value. For instance, sensor data may be marked with “T_{R1}+T_{A}” to represents an actual timestamp for the sensor data relative to the reference time value.

Step 604 communicates the marked sensor data to an entity. A sensor system, for instance, can transmit the marked sensor data to one or more external functionalities to enable the marked sensor data to be leveraged for various purposes.

According to various implementations, this method can be periodically and/or continuously performed to generate a stream of sensor data that is timestamped with updated aligned time values.

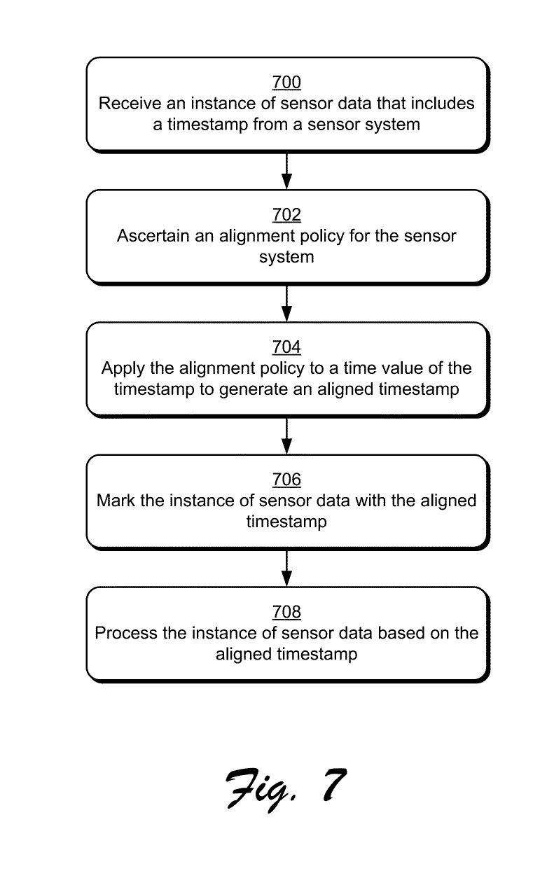

FIG. 7 is a flow diagram that describes steps in a method in accordance with one or more embodiments. The method, for instance, describes an example way of time-aligning sensor data based on a reference time base in accordance with one or more implementations.

Step 700 receives an instance of sensor data that includes a timestamp from a sensor system. The sensor alignment module 120, for instance, receives sensor data that has been marked with a timestamp by a sensor system.

Step 702 ascertains an alignment policy for the sensor system. Examples of different types of alignment policies are discussed above. In at least some implementations, an alignment policy is specific to a particular sensor system, e.g., sensor systems of a particular group of sensor systems may each be associated with a different alignment policy. With reference to the alignment table 314 discussed above, for instance, an identifier for the sensor system can be used to look up an alignment policy for the sensor system.

Step 704 applies the alignment policy to a time value of the timestamp to generate an aligned timestamp. Examples of different ways of applying an alignment policy are discussed above. An alignment policy, for instance, can be added to a time value, multiplied by the time value, utilized as a variable in a time alignment equation, and so forth. As mentioned above, an alignment policy may be based on a single parameter, multiple different parameters, an algorithm that may include a single value input and/or multiple value inputs, and so forth. Thus, implementations of alignment policies may range from simple values that can be applied to sensor data, to more complex combinations of different variables and/or algorithms that can be applied to sensor data according to techniques discussed herein.

Step 706 marks the instance of sensor data with the aligned timestamp. The aligned timestamp, for instance, can be used to replace the original timestamp or can be used as an addition to the original timestamp to indicate that the instance of sensor data is time aligned.

Step 708 processes the instance of sensor data based on the aligned timestamp. The sensor data, for example, may be arranged with other sensor data based on respective timestamps, e.g., chronologically. For instance, the sensor data may be placed in a series of sensor data based on a time value of the aligned timestamp. Alternatively or additionally, different instances of sensor data with the same and/or similar timestamps (e.g., aligned timestamps) may be grouped together to represent a collection of sensed phenomena that occurred at a particular time.

According to various implementations, this method can be performed periodically and/or continuously to provide a stream of time-aligned sensor data from a sensor system.

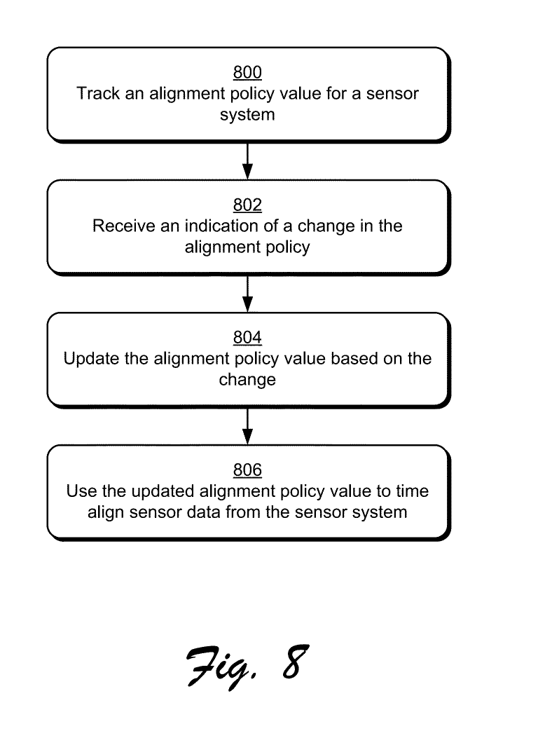

FIG. 8 is a flow diagram that describes steps in a method in accordance with one or more embodiments. The method, for instance, describes an example way of tracking alignment policies for sensor systems in accordance with one or more implementations.

Step 800 tracks an alignment policy value for a sensor system. As discussed above, for example, the alignment table 316 maintains alignment policy values for different sensor systems.

Step 802 receives an indication of a change in the alignment policy. The indication of the change may indicate various alterations in the alignment policy. For example, an offset between an internal clock of a sensor system and a master time clock may change in response to various events. An internal clock rate of a sensor system may also change. Such changes may occur in response to different events, such as based on a change in sampling frequency, a change in power levels in a sensor system (e.g., a change in input voltage), a change in usage scenario, and so forth. Various other types of changes to different types of alignment policies may be detected.

According to one or more implementations, the indication of the change may be received in various ways. For instance, the sensor system may communicate a notification (e.g., to the sensor alignment module 120) that includes the indication of the change. As another example, a functionality that is external to the sensor system may detect the change. The sensor alignment module 120, for example, may monitor a sampling rate and/or an internal clock of the sensor system, and thus may detect a change in the sampling rate and/or internal clock.

Alternatively or additionally, the sensor alignment module 120 may query the sensor system for its internal clock reading and/or clock rate, such as periodically, continuously, and/or in response to various events. The internal clock reading and/or clock rate can be compared to that of the master time clock 114 to determine an alignment policy, e.g., whether a change in an alignment policy for the sensor system has occurred. Thus, a change to an alignment policy may be detected in a variety of different ways.

Step 804 updates the alignment policy value based on the change. For instance, a table entry for the sensor system can be updated (e.g., in the alignment table 316) to indicate the change. An existing alignment policy for the sensor system, for example, can be replaced or augmented with an updated alignment policy value that reflects a change in the existing alignment policy.

Step 806 uses the updated alignment policy value to time align sensor data from the sensor system. For instance, the method discussed above with reference to FIG. 7 can be performed utilizing the updated alignment policy. Thus, a time alignment process can switch from using one alignment policy to using an updated alignment policy. In at least some implementations, this switch may occur dynamically (e.g., “mid-stream”) while sensor data is being streamed from a sensor system.

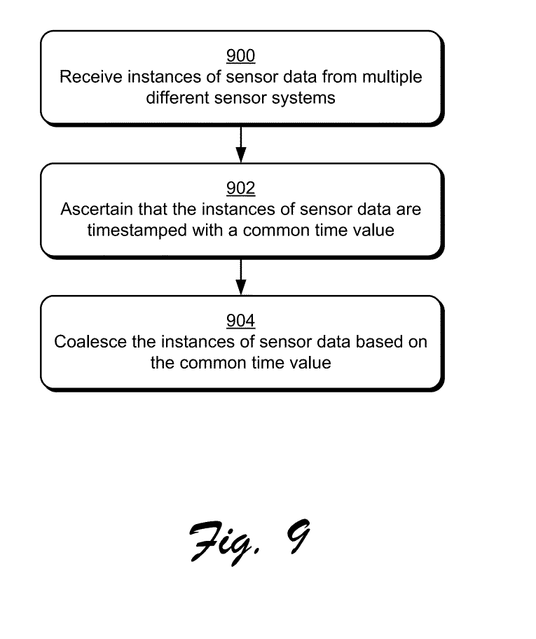

FIG. 9 is a flow diagram that describes steps in a method in accordance with one or more embodiments. The method, for instance, describes an example way of coalescing sensor data from different sensor systems in accordance with one or more implementations.

Step 900 receives instances of sensor data from multiple different sensor systems. The sensor systems, for instance, may reside on a single device, e.g., the computing device 102. Alternatively or additionally, at least some of the sensor systems may reside on different devices. For example, one or more of the sensor systems may reside on the computing device 102, while one or more others of the sensor systems may reside on the remote device 122. These variations are presented for purpose of example only, and it is to be appreciated that the sensor systems may reside at a variety of different locations, devices, and/or systems.

Step 902 ascertains that the instances of sensor data are timestamped with a common time value. For instance, the instances of sensor data may be time-aligned to a common time value according to various techniques discussed herein.

Step 904 coalesces the instances of sensor data based on the common time value. The instances of sensor data, for example, are aligned to a particular time value, e.g., an instance in time. In at least some embodiments, the coalesced sensor data may be integrated into an aggregated set of sensor data that includes other instances of sensor data that are coalesced around different common time values. The coalesced sensor data, for example, may be included as part of a timeline of sensor data that tracks sets of coalesced sensor data from different sensor systems over a period of time.

Thus, sensor data from a variety of different sensor systems may be time-aligned using different alignment techniques, and may be matched together based on common time-aligned time values. In at least some embodiments, this enables a wide variety of different types of sensed phenomena to be time-aligned to provide a rich state awareness of an environment of interest. As discussed herein, sensed phenomena may not only include physical phenomena, but may include logical phenomena and other environmental and/or system attributes.

Having considered the foregoing example aspects of techniques discussed herein, consider now a discussion of example systems and devices that may be employed to implement aspects of techniques in one or more embodiments.

Example System and Device

FIG. 10 illustrates an example system generally at 1000 that includes an example computing device 1002 that is representative of one or more computing systems and/or devices that may implement various techniques described herein. For example, the computing device 102 and/or the remote device 122 discussed above can be embodied as the computing device 1002. The computing device 1002 may be, for example, a server of a service provider, a device associated with the client (e.g., a client device), an on-chip system, and/or any other suitable computing device or computing system.

The example computing device 1002 as illustrated includes a processing system 1004, one or more computer-readable media 1006, and one or more Input/Output (I/O) Interfaces 1008 that are communicatively coupled, one to another. Although not shown, the computing device 1002 may further include a system bus or other data and command transfer system that couples the various components, one to another. A system bus can include any one or combination of different bus structures, such as a memory bus or memory controller, a peripheral bus, a universal serial bus, and/or a processor or local bus that utilizes any of a variety of bus architectures. A variety of other examples are also contemplated, such as control and data lines.

The processing system 1004 is representative of functionality to perform one or more operations using hardware. Accordingly, the processing system 1004 is illustrated as including hardware element 1010 that may be configured as processors, functional blocks, and so forth. This may include implementation in hardware as an application specific integrated circuit or other logic device formed using one or more semiconductors. The hardware elements 1010 are not limited by the materials from which they are formed or the processing mechanisms employed therein. For example, processors may be comprised of semiconductor(s) and/or transistors (e.g., electronic integrated circuits (ICs)). In such a context, processor-executable instructions may be electronically-executable instructions.

The computer-readable media 1006 is illustrated as including memory/storage 1012. The memory/storage 1012 represents memory/storage capacity associated with one or more computer-readable media. The memory/storage 1012 may include volatile media (such as random access memory (RAM)) and/or nonvolatile media (such as read only memory (ROM), Flash memory, optical disks, magnetic disks, and so forth). The memory/storage 1012 may include fixed media (e.g., RAM, ROM, a fixed hard drive, and so on) as well as removable media (e.g., Flash memory, a removable hard drive, an optical disc, and so forth). The computer-readable media 1006 may be configured in a variety of other ways as further described below.

Input/output interface(s) 1008 are representative of functionality to allow a user to enter commands and information to computing device 1002, and also allow information to be presented to the user and/or other components or devices using various input/output devices. Examples of input devices include a keyboard, a cursor control device (e.g., a mouse), a microphone (e.g., for voice recognition and/or spoken input), a scanner, touch functionality (e.g., capacitive or other sensors that are configured to detect physical touch), a camera (e.g., which may employ visible or non-visible wavelengths such as infrared frequencies to detect movement that does not involve touch as gestures), and so forth. Examples of output devices include a display device (e.g., a monitor or projector), speakers, a printer, a network card, tactile-response device, and so forth. Thus, the computing device 1002 may be configured in a variety of ways as further described below to support user interaction.

Various techniques may be described herein in the general context of software, hardware elements, or program modules. Generally, such modules include routines, programs, objects, elements, components, data structures, and so forth that perform particular tasks or implement particular abstract data types. The terms “module,” “functionality,” and “component” as used herein generally represent software, firmware, hardware, or a combination thereof The features of the techniques described herein are platform-independent, meaning that the techniques may be implemented on a variety of commercial computing platforms having a variety of processors.

An implementation of the described modules and techniques may be stored on or transmitted across some form of computer-readable media. The computer-readable media may include a variety of media that may be accessed by the computing device 1002. By way of example, and not limitation, computer-readable media may include “computer-readable storage media” and “computer-readable signal media.”

“Computer-readable storage media” may refer to media and/or devices that enable persistent storage of information in contrast to mere signal transmission, carrier waves, or signals per se. Computer-readable storage media do not include signals per se. The computer-readable storage media includes hardware such as volatile and non-volatile, removable and non-removable media and/or storage devices implemented in a method or technology suitable for storage of information such as computer readable instructions, data structures, program modules, logic elements/circuits, or other data. Examples of computer-readable storage media may include, but are not limited to, RAM, ROM, EEPROM, flash memory or other memory technology, CD-ROM, digital versatile disks (DVD) or other optical storage, hard disks, magnetic cassettes, magnetic tape, magnetic disk storage or other magnetic storage devices, or other storage device, tangible media, or article of manufacture suitable to store the desired information and which may be accessed by a computer.

“Computer-readable signal media” may refer to a signal-bearing medium that is configured to transmit instructions to the hardware of the computing device 1002, such as via a network. Signal media typically may embody computer readable instructions, data structures, program modules, or other data in a modulated data signal, such as carrier waves, data signals, or other transport mechanism. Signal media also include any information delivery media. The term “modulated data signal” means a signal that has one or more of its characteristics set or changed in such a manner as to encode information in the signal. By way of example, and not limitation, communication media include wired media such as a wired network or direct-wired connection, and wireless media such as acoustic, radio frequency (RF), infrared, and other wireless media.

As previously described, hardware elements 1010 and computer-readable media 1006 are representative of instructions, modules, programmable device logic and/or fixed device logic implemented in a hardware form that may be employed in some embodiments to implement at least some aspects of the techniques described herein. Hardware elements may include components of an integrated circuit or on-chip system, an application-specific integrated circuit (ASIC), a field-programmable gate array (FPGA), a complex programmable logic device (CPLD), and other implementations in silicon or other hardware devices. In this context, a hardware element may operate as a processing device that performs program tasks defined by instructions, modules, and/or logic embodied by the hardware element as well as a hardware device utilized to store instructions for execution, e.g., the computer-readable storage media described previously.

Combinations of the foregoing may also be employed to implement various techniques and modules described herein. Accordingly, software, hardware, or program modules and other program modules may be implemented as one or more instructions and/or logic embodied on some form of computer-readable storage media and/or by one or more hardware elements 1010. The computing device 1002 may be configured to implement particular instructions and/or functions corresponding to the software and/or hardware modules. Accordingly, implementation of modules that are executable by the computing device 1002 as software may be achieved at least partially in hardware, e.g., through use of computer-readable storage media and/or hardware elements 1010 of the processing system. The instructions and/or functions may be executable/operable by one or more articles of manufacture (for example, one or more computing devices 1002 and/or processing systems 1004) to implement techniques, modules, and examples described herein.

As further illustrated in FIG. 10, the example system 1000 enables ubiquitous environments for a seamless user experience when running applications on a personal computer (PC), a television device, and/or a mobile device. Services and applications run substantially similar in all three environments for a common user experience when transitioning from one device to the next while utilizing an application, playing a video game, watching a video, and so on.

In the example system 1000, multiple devices are interconnected through a central computing device. The central computing device may be local to the multiple devices or may be located remotely from the multiple devices. In one embodiment, the central computing device may be a cloud of one or more server computers that are connected to the multiple devices through a network, the Internet, or other data communication link.

In one embodiment, this interconnection architecture enables functionality to be delivered across multiple devices to provide a common and seamless experience to a user of the multiple devices. Each of the multiple devices may have different physical requirements and capabilities, and the central computing device uses a platform to enable the delivery of an experience to the device that is both tailored to the device and yet common to all devices. In one embodiment, a class of target devices is created and experiences are tailored to the generic class of devices. A class of devices may be defined by physical features, types of usage, or other common characteristics of the devices.

In various implementations, the computing device 1002 may assume a variety of different configurations, such as for computer 1014, mobile 1016, and television 1018 uses. Each of these configurations includes devices that may have generally different constructs and capabilities, and thus the computing device 1002 may be configured according to one or more of the different device classes. For instance, the computing device 1002 may be implemented as the computer 1014 class of a device that includes a personal computer, desktop computer, a multi-screen computer, laptop computer, netbook, and so on.

The computing device 1002 may also be implemented as the mobile 1016 class of device that includes mobile devices, such as a mobile phone, portable music player, portable gaming device, a tablet computer, a multi-screen computer, and so on. The computing device 1002 may also be implemented as the television 1018 class of device that includes devices having or connected to generally larger screens in casual viewing environments. These devices include televisions, set-top boxes, gaming consoles, and so on.

The techniques described herein may be supported by these various configurations of the computing device 1002 and are not limited to the specific examples of the techniques described herein. For example, functionalities discussed with reference to the computing device 102 and/or the remote device 122 may be implemented all or in part through use of a distributed system, such as over a “cloud” 1020 via a platform 1022 as described below.

The cloud 1020 includes and/or is representative of a platform 1022 for resources 1024. The platform 1022 abstracts underlying functionality of hardware (e.g., servers) and software resources of the cloud 1020. The resources 1024 may include applications and/or data that can be utilized while computer processing is executed on servers that are remote from the computing device 1002. Resources 1024 can also include services provided over the Internet and/or through a subscriber network, such as a cellular or Wi-Fi network.

The platform 1022 may abstract resources and functions to connect the computing device 1002 with other computing devices. The platform 1022 may also serve to abstract scaling of resources to provide a corresponding level of scale to encountered demand for the resources 1024 that are implemented via the platform 1022. Accordingly, in an interconnected device embodiment, implementation of functionality described herein may be distributed throughout the system 1000. For example, the functionality may be implemented in part on the computing device 1002 as well as via the platform 1022 that abstracts the functionality of the cloud 1020.

Discussed herein are a number of methods that may be implemented to perform techniques discussed herein. Aspects of the methods may be implemented in hardware, firmware, or software, or a combination thereof. The methods are shown as a set of steps that specify operations performed by one or more devices and are not necessarily limited to the orders shown for performing the operations by the respective blocks. Further, an operation shown with respect to a particular method may be combined and/or interchanged with an operation of a different method in accordance with one or more implementations. Aspects of the methods can be implemented via interaction between various entities discussed above with reference to the environment 100.

### CONCLUSION

Although the example implementations have been described in language specific to structural features and/or methodological acts, it is to be understood that the implementations defined in the appended claims is not necessarily limited to the specific features or acts described. Rather, the specific features and acts are disclosed as example forms of implementing the claimed features.

What is claimed is:

1. A system comprising:
at least one processor; and
one or more computer-readable storage media including instructions stored thereon that, responsive to execution by the at least one processor, cause the system perform operations including:
receiving an instance of sensor data that includes a timestamp from a sensor system;
ascertaining an alignment policy for the sensor system;
applying the alignment policy to a time value of the timestamp to generate an aligned timestamp; and
marking the instance of sensor data with the aligned timestamp to generate a time-aligned version of the instance of sensor data.

2. A system as recited in claim 1, wherein the timestamp from the sensor system is based on at least one of an internal time clock of the sensor system or a time clock that is implemented externally to the sensor system.

3. A system as recited in claim 1, wherein said ascertaining comprises looking up the alignment policy in a storage location that tracks alignment policies for different sensor systems.

4. A system as recited in claim 1, wherein the alignment policy describes a relationship between an internal time clock of the sensor system and a reference time value for a computing device.

5. A system as recited in claim 1, wherein the alignment policy is relative to an operating frequency of the sensor system.

6. A system as recited in claim 1, wherein said applying causes the time value of the timestamp to be aligned with a reference time value.

7. A system as recited in claim 1, wherein said marking comprises inserting the aligned timestamp into a header of the instance of sensor data.

8. A system as recited in claim 1, wherein said marking comprises incorporating the aligned timestamp into metadata that is associated with the instance of sensor data.

9. A system as recited in claim 1, wherein the sensor system resides on a particular computing device, and wherein the operations further comprise:
receiving a time-aligned version of a different instance of sensor data from a different sensor system that is operably associated with a different computing device;
ascertaining that a timestamp of the different instance of sensor data and the aligned timestamp of the instance of sensor data correspond to a common time value; and
coalescing the different instance of sensor data and the instance of sensor data based on the common time value.

10. A system as recited in claim 10, wherein said coalescing comprises aggregating the different instance of sensor data and the instance of sensor data into a collection of sensor data from different computing devices, the collection of sensor data being arranged based on time values for respective instances of sensor data.

11. A system as recited in claim 1, wherein the operations further include periodically refreshing the alignment policy.

12. A system as recited in claim 1, wherein the operations further comprise:
receiving an indication of a change in the alignment policy; and
updating a value of the alignment policy based on the change to enable one or more subsequent instances of sensor data from the sensor system to be time-aligned based on the updated value.

13. One or more computer-readable storage media including instructions stored thereon that are executable to perform operations comprising:
propagating, via a functionality that is external to a sensor system, an instance of a reference time value to the sensor system;
receiving sensor data from the sensor system that is marked with a timestamp based on the instance of the reference time value; and
processing the sensor data based on the timestamp.

14. One or more computer-readable storage media as described in claim 13, wherein the reference time value is based on a processor clock rate of a computing device with which the sensor system is operably associated.

15. One or more computer-readable storage media as described in claim 13, wherein the timestamp includes the reference time value plus a delta value that indicates an elapsed time from the reference time value.

16. One or more computer-readable storage media as described in claim 13, wherein the operations further comprise:
propagating, via the functionality, the instance of the reference time value to a different sensor system in parallel with propagating the instance of the reference time value to the sensor system to enable sensor data from the different sensor system to be marked based on the instance of the reference time value.

17. A computer-implemented method comprising:
tracking an alignment policy value for a sensor system;
receiving an indication of a change in the alignment policy; and
updating the alignment policy value based on the change to enable sensor data from the sensor system to be time-aligned based on the updated alignment policy value.

18. A computer-implemented method as described in claim 17, wherein the alignment policy describes a relationship between an internal time clock of the sensor system and a reference time value for a computing device with which the sensor system is operably associated.

19. A computer-implemented method as described in claim 17, wherein the alignment policy relates to a sampling frequency of the sensor system, and wherein the change indicates a change in the sampling frequency of the sensor system.

20. A computer-implemented method as described in claim 17, wherein said receiving the indication occurs in response to a query to the sensor system for information related to the alignment policy.
